(19) United States
(12) Patent Application Publication
(10) Pub. No.: US 2013/0032854 A1
(43) Pub. Date: Feb. 7, 2013

(54) Rectirier

(71) Applicant: Chao-Cheng LUI, Taipei (TW)

(72) Inventor: Chao-Cheng LUI, Taipei (TW)

(21) Appl. No.: 13/136,348

(22) Filed: Aug. 1, 2011

(51) Int. Cl. H01L 29/772

(52) U.S. Cl. 257/133; 257/E29.242

(57) ABSTRACT

The rectifier in this invention is connected in series with two field effect transistor, comprises: the source S1 of first N-channel FET F1 and the source S2 of second N-channel FET F2 are directly connected together, the gate G1 of first N-channel FET F1 and the gate G2 of second N-channel FET F2 are connected together form a control terminal GA, the drain D1 of first N-channel FET F1 form a input terminal D1, the drain D2 of second N-channel FET F2 form a output terminal D2, the body diode DA of first N-channel FET F1 and the body diode DB of second N-channel FET F2, are back-to-back series connected together, the right side equivalent circuit F are first N-channel FET F1 and second N-channel FET F2 equivalent circuit, form a rectifier F of the present invention.

### BACKGROUND OF THE INVENTION

1. The Field of the Invention

The present invention relates generally to AC rectifier, the includes series-connected circuit of first and second N-channel field effect transistor or first and second P-channel field effect transistor to rectify an alternating current (AC)power source input voltage and provide a direct current (DC) output voltage.

2. Description of Related Art

The present invention related to enhancement mode two N-channel field effect transistor or two P-channel field effect transistor form a rectifier for rectification circuit, in prior art such as a integratable synchronous rectifier are taught by the U.S. Pat. No. 5,173,849, its comprising: switch and driver, the structure and operation theorem of electric circuit are difference the present invention.

### SUMMARY OF THE INVENTION

In order to provide rectifier devices that may elevate the efficiency and simplify circuit of rectification circuit, the present invention is proposed the following object:

The first object of the invention is to provide rectifier for rectification circuit that eliminate drawback of high power consumption of prior arc rectification circuit utilizing diode, or synchronous rectifier circuit utilizing a synchronous rectifier driver and a power MOSFET.

The second object of the invention is to provide a rectification circuit. According to the defects of the prior arc technology discussed above, a novel solution, the rectifier is proposed in the present invention, which provides high efficiency in rectification circuit.

### BRIEF DESCRIPTION OF THE INVENTION

Embodiment of the invention will be described in more detail hereinafter with reference to the accompanying drawing. In the drawings:

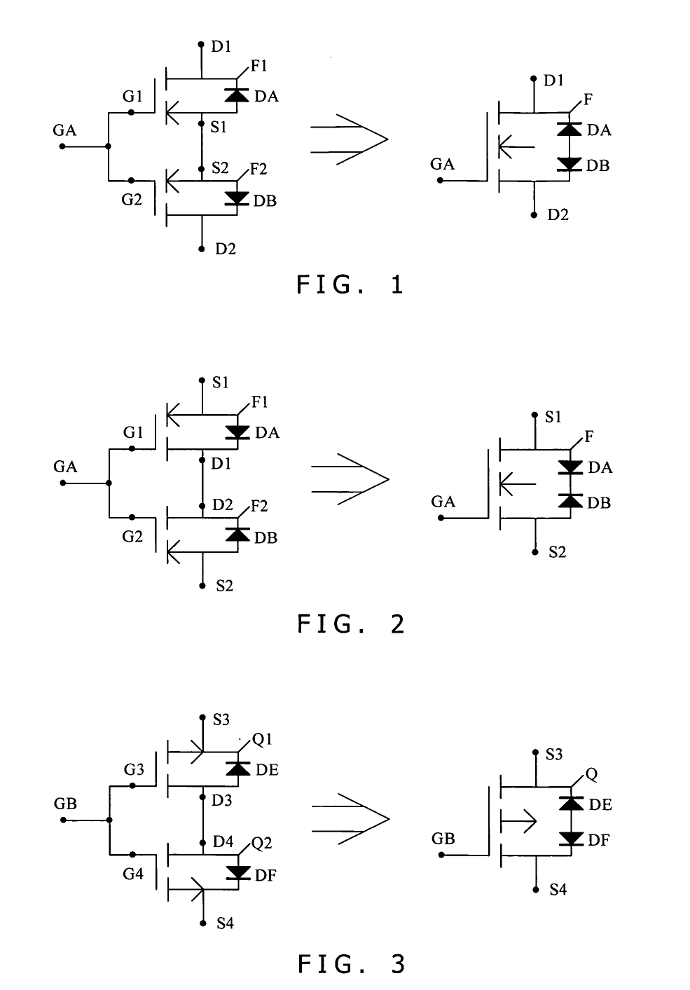

FIG. 1 shows a circuit diagram of a first embodiment of the present invention.

FIG. 2 shows a circuit diagram of a second embodiment of the present invention.

FIG. 3 shows a circuit diagram of a third embodiment of the present invention.

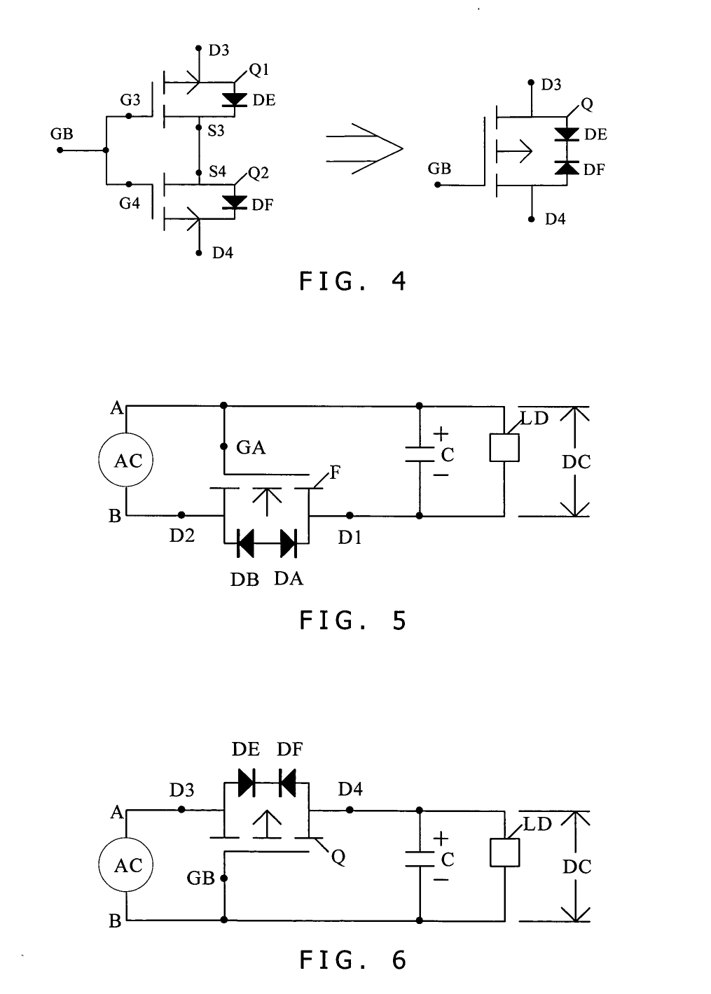

FIG. 4 shows a circuit diagram of a fourth embodiment of the present invention.

FIG. 5 shows a circuit diagram of a first rectification circuit of the present invention.

FIG. 6 shows a circuit diagram of a second rectification circuit of the present Invention.

### DESCRIPTION OF THE PREFERRED EMBODIMENT

FIG. 1 shows a circuit diagram of a first embodiment of the present invention. In FIG. 1, the series-connected circuit of first N-channel field effect transistor (FET) F1 and second N-channel FET F2, the source S1 of first N-channel FET F1 and the source S2 of second N-channel FET F2 are directly connected together, the gate G1 of first N-channel FET F1 and the gate G2 of second N-channel FET F2 are connected together form a control terminal GA, the drain D1 of first N-channel FET F1, form a input terminal D1, the drain D2 of second N-channel FET F2, form a output terminal D2, the body diode DA of first N-channel FET F1, the body diode DB of second N-channel FET F2, are back-to-back series connected together, the right side equivalent circuit F of FIG. 1 are first N-channel FET F1 and second N-channel FET F2 equivalent circuit, form a rectifier F of the present invention.

In FIG. 1, when control terminal GA is positive voltage, the drain D1 of first N-channel FET F1 and the drain D2 of second N-channel FET F2 is turn on; when control terminal GA is negative voltage, the drain D1 of first N-channel FET F1 and the drain D2 of second N-channel FET F2 is turn off.

FIG. 2 shows a circuit diagram of a second embodiment of the present invention. In FIG. 2, the series-connected circuit of first N-channel FET F1 and second N-channel FET F2, the drain D1 of first N-channel FET F1 and the drain D2 of the second N-channel FET F2 are directly connected together, the gate G1 of first N-channel FET F1 and the gate G2 of second N-channel FET F2 are connected together form a control terminal GA, the source S1 of first N-channel FET F1, form a input terminal S1, the source S2 of second N-channel FET F2, form a output terminal S2, the body diode DA of first N-channel FET F1, the body diode DB of the second N-channel FET F2, are face-to-face series connected together, the right side equivalent circuit F of FIG. 2 are first N-channel FET F1 and second N-channel FET F2 equivalent circuit, form a rectifier F of the present invention.

In FIG. 2, when control terminal GA is positive voltage, the source S1 of first N-channel FET F1 and the source S2 of second N-channel FET F2 is turn on; when control terminal GA is negative voltage, the source S1 of first N-channel FET F1 and the source S2 of second N-channel FET F2 is turn off.

FIG. 3 shows a circuit diagram of a third embodiment of the present invention. In FIG. 3, the series-connected circuit of first P-channel FET Q1 and second P-channel FET Q2, the drain D3 of first P-channel FET Q1 and the drain D4 of the second P-channel FET Q2 are directly connected together, the gate G3 of first P-channel FET Q1 and the gate G4 of second P-channel FET Q2 are connected together form a control terminal GB, the source S3 of first P-channel FET Q1, form a input terminal S3, the source S4 of second P-channel FET Q2, form a output terminal S4, the body diode DE of first P-channel FET Q1, the body diode DF of second P-channel FET Q2, are back-to-back series connected together, the right side equivalent circuit Q of FIG. 3 are first P-channel FET Q1 and second P-channel FET Q2 equivalent circuit, form a rectifier Q of the present invention.

In FIG. 3, when control terminal GB is negative voltage, the source S3 of first P-channel FET Q1 and the source S4 of the second P-channel FET Q2 is turn on; when control terminal GB is positive voltage, the source S3 of first P-channel FET Q1 and the source S4 of second P-channel FET Q2 is turn off.

FIG. 4 shows a circuit diagram of a second embodiment of the present invention. In FIG. 4, the series-connected circuit of first P-channel FET Q1 and second P-channel FET Q2, the source S3 of first P-channel FET Q1 and the source S4 of second P-channel FET Q2 are directly connected together, the gate G3 of first P-channel FET Q1 and the gate G4 of second P-channel FET Q2 are connected together form a control terminal GB, the drain D3 of first P-channel FET Q1, form a input terminal D3, the drain D4 of second P-channel FET Q2, form a output terminal D4, the body\diode DE of the first P-channel FET Q1, the body diode DF of second P-channel FET Q2, are face-to-face series connected together, the right side equivalent circuit Q of FIG. 4 are the first P-channel FET Q1 and second P-channel FET Q2 equivalent circuit, form a rectifier Q of the present invention.

In FIG. 4, when control terminal GB is negative voltage, the drain D3 of first P-channel FET Q1 and the drain D4 of second P-channel FET Q2 is turn on; when control terminal GA is positive voltage, the drain D3 of first P-channel FET Q1 and the drain D4 of second P-channel FET Q2 is turn off.

In FIG. 5, shows a circuit diagram of a first rectification circuit of the present invention. In FIG. 5, while the voltage at terminal A of Alternating Current (AC) power source is positive, terminal B is negative, the output terminal D2 of rectifier F is negative voltage, the control terminal GA of rectifier F is positive voltage, the rectifier F is turn on, the current of AC power source passes through the filter capacity C, load LD, input terminal D1 and output terminal D2 of rectifier F, and back to terminal B of the AC power source, the filter capacity C voltage is Direct Current (DC), the DC is load LD voltage; when the voltage at terminal A of AC power source is negative, terminal B is positive, the output terminal D2 of rectifier F is positive voltage, the control terminal GA of rectifier F is negative voltage, the current of AC power source con not passes through back-to-back of body diode DA and body diode DB of rectifier F, the rectifier F is turn off. Hence, function of half-wave rectify can be achieved.

In FIG. 6, shows a circuit diagram of a second rectification circuit of the present invention. In FIG. 6, while the voltage at terminal A of AC power source is positive, terminal B is negative voltage, the input terminal D3 of rectifier Q is positive, the control terminal GB of rectifier Q is negative voltage, the rectifier Q is turn on, the current of AC power source passes through the input terminal D3 and output terminal D4 of rectifier Q, filter capacity C, load LD, and back to terminal B of the AC power source, the filter capacity C voltage is Direct Current (DC), the DC is load LD voltage; when the voltage at terminal A of AC power source is negative, terminal B is positive, the output terminal D3 of rectifier Q is negative voltage, the control terminal GB of rectifier Q is positive voltage, the current of AC power source con not passes through face-to-face of body diode DF and body diode DE of rectifier Q, the rectifier Q is turn off. Hence, function of half-wave rectify can be achieved.

What is claimed is:

1. A rectifier is for rectification circuit on the source of first field effect transistor and the source of second field effect transistor are directly connected together, characterized in that it comprises:
a control terminal is a gate of said first field effect transistor and a gate of said second field effect transistor connected together in a terminal;
an input terminal is a drain of said first field effect transistor; and
an output terminal is a drain of said second field effect transistor.

2. A rectifier as claimed in claim 1, wherein said first field effect transistor and said second field effect transistor each comprises an N-channel field effect transistor.

3. A rectifier as claimed in claim 1, wherein said first field effect transistor and said second field effect transistor each comprises a P-channel field effect transistor.

4. A rectifier as claimed in claim 1, wherein said control terminal coupled between a first terminal of said AC power source and said load of said positive DC voltage terminal.

5. A rectifier as claimed in claim 1, wherein said output terminal coupled to a second terminal of said AC power source.

6. A rectifier as claimed in claim 1, wherein said input terminal coupled to said load of said negative DC voltage terminal.

7. A rectifier as claimed in claim 1, wherein said control terminal coupled between a second terminal of said AC power source and said load of said negative DC voltage terminal.

8. A rectifier as claimed in claim 1, wherein said input terminal coupled to a first terminal of said AC power source.

9. A rectifier as claimed in claim 1, wherein said output terminal coupled to said load of said positive DC voltage terminal.

10. A rectifier is for rectification circuit on the drain of first field effect transistor and the drain of second field effect transistor are directly connected together, characterized in that it comprises:
a control terminal is a gate of said first field effect transistor and a gate of said second field effect transistor connected together in a terminal;
an input terminal is a source of said first field effect transistor; and
an output terminal is a source of said second field effect transistor.

11. A rectifier as claimed in claim 10, wherein said first field effect transistor and said second field effect transistor each comprises an N-channel field effect transistor.

12. A rectifier as claimed in claim 10, wherein said first field effect transistor and said second field effect transistor each comprises a P-channel field effect transistor.

13. A rectifier as claimed in claim 10, wherein said control terminal coupled between a first terminal of said AC power source and said load of said positive DC voltage terminal.

14. A rectifier as claimed in claim 10, wherein said output terminal coupled to a second terminal of said AC power source.

15. A rectifier as claimed in claim 10, wherein said input terminal coupled to said load of said negative DC voltage terminal.

16. A rectifier as claimed in claim 6, wherein said control terminal coupled between a second terminal of said AC power source and said load of said negative DC voltage terminal.

17. A rectifier as claimed in claim 10, wherein said input terminal coupled to a first terminal of said AC power source.

18. A rectifier as claimed in claim 10, wherein said output terminal coupled to said load of said positive DC voltage terminal.
